(19) United States
(12) Patent Application Publication
(10) Pub. No.: US 2024/0324425 A1
(43) Pub. Date: Sep. 26, 2024

(54) DISPLAY APPARATUS AND METHOD OF MANUFACTURING THE SAME

(71) Applicant: Samsung Display Co., Ltd., Yongin-si (KR)

(72) Inventor: Hyuneok Shin, Yongin-si (KR)

(21) Appl. No.: 18/525,629

(22) Filed: Nov. 30, 2023

(30) Foreign Application Priority Data
Mar. 24, 2023 (KR) 10-2023-0039044
Jun. 16, 2023 (KR) 10-2023-0077453

(51) Int. Cl. H10K 59/80

(52) U.S. Cl. CPC H10K 59/8792; H10K 59/879

(57) ABSTRACT

A display apparatus includes: a substrate; a plurality of barrier layers on the substrate and spaced apart from each other, the plurality of barrier layers being transparent; a light-absorbing layer contacting sides of each of the barrier layers; and a highly refractive index layer on the light-absorbing layer.

### CROSS-REFERENCE TO RELATED APPLICATIONS

The present application claims priority to and the benefit of Korean Patent Application No. 10-2023-0039044, filed on Mar. 24, 2023, and Korean Patent Application No. 10-2023-0077453, filed on Jun. 16, 2023, in the Korean Intellectual Property Office, the entire content of which is incorporated herein by reference.

### BACKGROUND

### 1. Field

Aspects of one or more embodiments relate to a display apparatus and a method of manufacturing the same.

### 2. Description of Related Art

Recently, the uses and applications of display apparatuses has been diversifying. In addition, as display apparatuses become relatively thinner and lighter in thickness and weight, the scope of their uses has expanded, and as display apparatuses are utilized in various fields, the demand for display apparatuses that provide high-quality images is increasing. Recently, display apparatuses have been utilized or incorporated into vehicles to provide video to users sitting in the driver's or passenger's seat.

The above information disclosed in this Background section is only for enhancement of understanding of the background and therefore the information discussed in this Background section does not necessarily constitute prior art.

### SUMMARY

Light emitted by a display apparatus located inside a vehicle may be reflected from the vehicle's windows and may reach the user. In this case, such reflected light may interfere with the driver's view of the road and create safety issues.

Aspects of one or more embodiments include a display apparatus in which the viewing angle of light emitted from the display apparatus is limited, and a method of manufacturing the display apparatus. However, these characteristics are merely illustrative, and the scope of embodiments according to the present disclosure are not limited thereto.

Additional aspects will be set forth in part in the description which follows and, in part, will be apparent from the description, or may be learned by practice of the presented embodiments of the disclosure.

According to some embodiments of the present disclosure, a display apparatus includes a substrate, a plurality of barrier layers on the substrate to be spaced apart from each other, the plurality of barrier layers being transparent, a light-absorbing layer contacting sides of each of barrier layers, and a highly refractive index layer on the light-absorbing layer.

According to some embodiments, each of the barrier layers may have a shape of a trapezoid.

According to some embodiments, each of the barrier layers may include a transparent inorganic material or transparent polyimide

According to some embodiments, each of the barrier layers may in lude silicon dioxide (SiO₂), which is a transparent inorganic material.

According to some embodiments, the light-absorbing layer may include amorphous silicon (a-Si) or silicon carbide (SiC).

According to some embodiments, a refractive index of the highly refractive index layer may be greater than or equal to 2 and less than or equal to 2.3.

According to some embodiments, the highly refractive index layer may include at least one selected from niobium pentoxide (Nb₂O₅), titanium dioxide (TiO₂), and tantalum pentoxide (Ta₂O₅).

According to some embodiments, the display apparatus may further include grooves that are empty spaces between the barrier layers, and an organic film filled in the grooves.

According to some embodiments, a refractive index of the organic film may be greater than or equal to 1.5 and less than or equal to 1.6.

According to some embodiments, the organic film may include transparent photosensitive polyimide (PSPI).

According to some embodiments of the present disclosure, a method of manufacturing a display apparatus includes forming a plurality of barrier layers to be on a substrate and to be spaced apart from each other, the plurality of barrier layers being transparent, forming a light-absorbing layer contacting sides of each of the barrier layers, and forming a highly refractive index layer on the light-absorbing layer.

According to some embodiments, the method may further include forming a light-absorbing layer-forming material by using a chemical vapor deposition (CVD) process and forming a light-absorbing layer by etching at least a portion of the light-absorbing layer-forming material.

According to some embodiments, the method may further include forming a light-absorbing layer by etching a portion of the light-absorbing layer-forming material arranged in a horizontal direction.

According to some embodiments, the method may further include forming a light-absorbing layer-forming material on each of the barrier layers, forming a highly refractive index layer-forming material on the light-absorbing layer-forming material, and forming a light-absorbing layer and a highly refractive index layer by etching at least a portion of the light-absorbing layer-forming material and the highly refractive index layer-forming material.

According to some embodiments, the method may further include forming a light-absorbing layer and a highly refractive index layer by etching a portion of the light-absorbing layer-forming material and the highly refractive index-forming material arranged in a horizontal direction.

According to some embodiments, each of the barrier layers may include a transparent inorganic material or transparent polyimide.

According to some embodiments, each of the barrier layers may include silicon dioxide (SiO₂), which is a transparent inorganic material.

According to some embodiments, the light-absorbing layer may include amorphous silicon (a-Si) or silicon carbide (SiC).

According to some embodiments, a refractive index of the highly refractive index layer may be greater than or equal to 2 and less than or equal to 2.3.

According to some embodiments, the highly refractive index layer may include at least one selected from niobium pentoxide (Nb₂O₅), titanium dioxide (TiO₂), and tantalum pentoxide (Ta₂O₅).

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a perspective view schematically illustrating a display apparatus according to some embodiments;

FIG. 2 is a cross-sectional view schematically illustrating the display apparatus taken along a line A-A′ of FIG. 1 according to some embodiments;

FIG. 3 is an equivalent circuit diagram of one pixel according to some embodiments;

FIG. 4 is a plan view schematically illustrating a display apparatus according to some embodiments;

FIGS. 5 through 7 are cross-sectional views schematically illustrating the display apparatus taken along a line B-B′ of FIG. 4 according to some embodiments;

FIG. 8 is a graph schematically illustrating reflectance according to an incident angle of light incident from a light-emitting layer to a refractive layer, depending on a refractive index of a highly refractive index layer according to some embodiments;

FIG. 9 is a cross-sectional view schematically illustrating lights incident on a light control layer according to some embodiments;

FIGS. 10A through 10F are cross-sectional views schematically illustrating a method of manufacturing a display apparatus according to some embodiments; and

FIGS. 11A through 11C are cross-sectional views schematically illustrating a method of manufacturing a display apparatus according to some embodiments.

### DETAILED DESCRIPTION

Reference will now be made in more detail to aspects of some embodiments, which are illustrated in the accompanying drawings, wherein like reference numerals refer to like elements throughout. In this regard, embodiments according to the present disclosure may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Because various modifications and various embodiments of the present disclosure are possible, specific embodiments are illustrated in the drawings and described in more detail in the detailed description. Effects and features of the present disclosure, and a method of achieving them will be apparent with reference to embodiments described below in more detail in conjunction with the drawings. However, embodiments according to the present disclosure are not limited to the embodiments disclosed herein, but may be implemented in a variety of forms.

Hereinafter, embodiments of the present disclosure will be described in more detail with reference to the accompanying drawings, and the same or corresponding components are denoted by the same reference numerals, and the same reference numerals are assigned and redundant explanations will be omitted.

In the following embodiments, the terms of the first and second, etc. were used for the purpose of distinguishing one element from other elements, not a limited sense.

In the following embodiments, the singular expression includes a plurality of expressions unless the context is clearly different.

In the following embodiments, the terms such as comprising or having are meant to be the features described in the specification, or the element s are present, and the possibility of one or more other features or elements will be added, is not excluded in advance.

In the following embodiments, when a portion such as a layer, a region, an element or the like is on other portions, this is not only when the portion is on other elements, but also when other elements are interposed therebetween.

In the drawings, for convenience of explanation, the sizes of elements may be exaggerated or reduced. For example, because the size and thickness of each component shown in the drawings are arbitrarily indicated for convenience of explanation, the present disclosure is not necessarily limited to the illustration.

In the present specification, in the case where some embodiments may be implemented in the present specification, a specific process order may be performed differently from the order described. For example, two processes described in succession may be substantially performed at the same time, or in an opposite order to an order to be described.

In the present specification, “A and/or B” is A, B, A and B, or any combination of A and/or B. In addition, in the present specification, “at least one of A and B” is A, B, A and B, or any combination of A and/or B.

In the following embodiments, when a layer, a region, a component, etc. are connected to each other, the layer, the region, and the components are directly connected to each other and/or the layer, the region, and the components may be indirectly connected to each other with other layers, other regions and other components interposed between the layer, the region, and the components. For example, when a layer, a region, a component, etc. are electrically connected to each other in the present specification, the layer, the region, the component, etc. are directly electrically connected to each other, and/or the layer, the region, the component, etc. are indirectly electrically connected to each other with other layers, other regions and other components interposed between the layer, the region, and the components.

The x-axis, the y-axis, and the z-axis are not limited to three axes on a Cartesian coordinate system, and may be interpreted in a broad sense including the same. For example, the x-axis, the y-axis, and the z-axis may be perpendicular to each other, but may refer to different directions that are not orthogonal to each other.

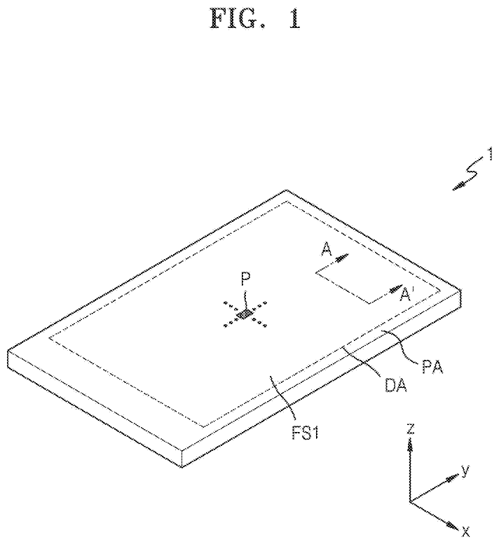

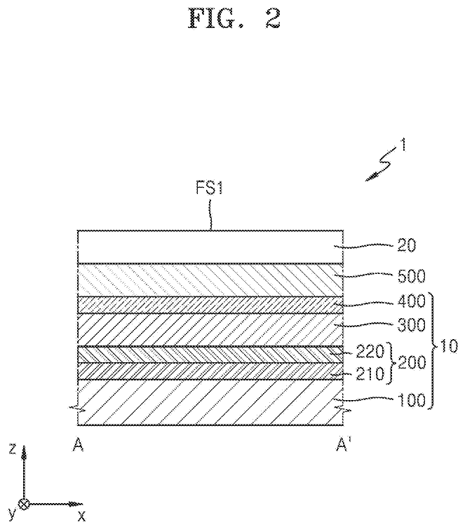

FIG. 1 is a perspective view schematically illustrating aspects of a display apparatus according to some embodiments. FIG. 2 is a cross-sectional view schematically illustrating aspects of the display apparatus taken along a line A-A′ of FIG. 1 according to some embodiments.

Referring to FIG. 1, a display apparatus 1 according to some embodiments may include a display area DA and a peripheral area PA. The peripheral area PA may be outside (e.g., in a periphery or outside a footprint of) the display area DA to surround the display area DA. Various wirings and a driving circuit portion that transmit electrical signals to be applied to the display area DA may be located in the peripheral area PA. The display apparatus 1 may display images by using light emitted from a plurality of pixels P arranged in the display area DA. Although FIG. 1 illustrates a single pixel P, as a person having ordinary skill in the art would appreciate, the display apparatus 1 may include any number of pixels P according to the design and size of the display apparatus 1.

Hereinafter, the case where the display apparatus 1 is an organic light-emitting display apparatus, will be described. However, embodiments according to the present disclosure are not limited thereto. The display apparatus 1 may be a display apparatus such as an organic light-emitting display apparatus, an inorganic light-emitting display apparatus or an inorganic electroluminescent (EL) display apparatus, or a quantum dot light-emitting display apparatus.

The display apparatus 1 may be implemented with various types of electronic devices. According to some embodiments, the display apparatus 1 may be a display apparatus for a vehicle. However, embodiments according to the present disclosure are not limited thereto.

As shown in FIG. 2, the display apparatus 1 may include a display panel 10, a light control layer 500, and a cover window 20. The display panel 10 may include a substrate 100, a display layer 200, an encapsulation layer 300, and a touch sensor layer 400, which are sequentially stacked to each other in a third direction (e.g., a z direction).

The substrate 100 may include a glass material or a polymer resin. For example, the substrate 100 may include a glass material including a main component of silicon oxide (SiOX), or a polymer resin, such as polyethersulfone, polyarylate, polyetherimide, polyethylene naphthalate, polyethylene terephthalate, polyphenylene sulfide, polyimide, polycarbonate, cellulose tri acetate, or cellulose acetate propionate.

The display layer 200 may be located on the substrate 100. The display layer 200 may include a pixel circuit layer 210 including a pixel circuit and insulating layers, and a display element layer 220 including a light-emitting diode. The display element layer 220 may be located on the pixel circuit layer 210, and a plurality of insulating layers may be arranged between the pixel circuit and the light-emitting diode. Some wirings and insulating layers of the pixel circuit layer 210 may extend to the peripheral area PA (e.g., referring to FIG. 1).

The encapsulation layer 300 may be located on the display layer 200. The encapsulation layer 300 may be configured to seal light-emitting diodes located in the display element layer 220. According to some embodiments, the encapsulation layer 300 may include at least one inorganic encapsulation layer and at least one organic encapsulation layer. At least one inorganic encapsulation layer may include one or more inorganic materials selected from the group consisting of aluminum oxide (Al₂O₃), titanium oxide (TiO₂), tantalum oxide (Ta₂O₅), zinc oxide (ZnO), silicon oxide (SiO₂), silicon nitride (SiNx), and silicon oxynitride (SiON). At least one organic encapsulation layer may include a polymer-based material. The polymer-based material may include an acryl-based resin, an epoxy-based resin, polyimide, polyethylene, or the like. According to some embodiments, at least one organic encapsulation layer may include acrylate.

A touch sensor layer 400 may be located on the encapsulation layer 300. The touch sensor layer 400 may be a layer for sensing a user's touch input (e.g., from a finger or stylus), and may be configured to sense a touch input by using at least one of various touch methods, such as a resistive layer method, a capacitive method, and the like. The touch sensor layer 400 may be located on a top surface of the encapsulation layer 300, as shown in FIG. 2. However, the touch sensor layer 400 may also be between the encapsulation layer 300 and the display layer 200. In addition, the touch sensor layer 400 may be separately formed and attached to the encapsulation layer 300, or the touch sensor layer 400 may be directly formed in a pattern shape on the encapsulation layer 300.

The light control layer 500 may be located on the touch sensor layer 400. The light control layer 500 may absorb external light or internal reflected light at least partially to limit a viewing angle of light emitted from the display element layer 220. For example, the light control layer 500 may allow light emitted perpendicular to a front surface FS1 of the display apparatus 1 to transmit and may block light emitted at an angle of about 45° or less with the front surface FS1 of the display apparatus 1. The light control layer 500 may be located in the display area DA. The light control layer 500 may include a transmission area through which light emitted from a light-emitting diode located in the display area DA passes outwards. The light control layer 500 may be separately formed and attached to the display panel 10.

The cover window 20 may be located on the display panel 10 and the light control layer 500. According to some embodiments, the cover window 20 may be coupled to a component thereunder, for example, the light control layer 500 through adhesive material such as an optically clear adhesive (OCA). The cover window 20 may be configured to protect the display panel 10 and the light control layer 500. The cover window 20 may include at least one selected from the group consisting of glass, sapphire, and plastic. The cover window 20 may be, for example, ultra-thin glass (UTG) or colorless polyimide (CPI).

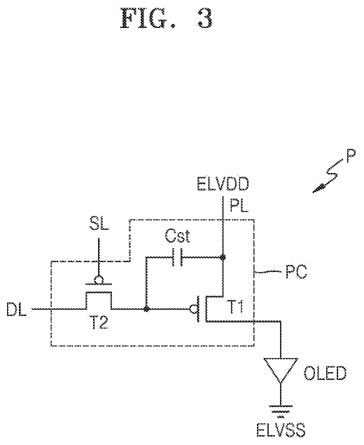

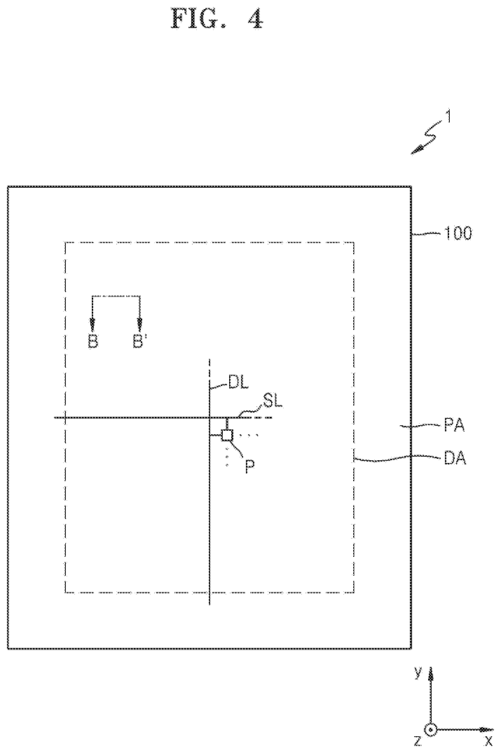

FIG. 3 is an equivalent circuit diagram of one pixel according to some embodiments, and FIG. 4 is a plan view schematically illustrating a display apparatus according to some embodiments.

Referring to FIGS. 3 and 4, a substrate 100 of a display apparatus 1 may be divided into a display area DA and a peripheral area PA. The display apparatus 1 may display images by using light emitted from a plurality of pixels P arranged in the display area DA.

Each of the pixels P may include a display element, such as an organic light-emitting diode (OLED) or an inorganic light-emitting diode, and may emit red, green, blue or white light. That is, each pixel P may be connected to a pixel circuit PC including a thin-film transistor (TFT), a storage capacitor Cst, and the like. The pixel circuit PC may be connected to a scan line SL, a data line DL crossing the scan line SL, and a driving voltage line PL. According to some embodiments, the scan line SL may extend in a first direction (an x direction), and the data line DL and the driving voltage line PL may extend in a second direction (a y direction).

Through driving of the pixel circuit PC, each pixel P may emit light, and the display area DA may provide a certain image by using light emitted from the pixels P. In the present specification, the pixel PX may be defined as a light-emitting area in which light of any one of red, green, blue or white is emitted, as described above.

The peripheral area PA may be an area in which the pixel PX is not located, and no image may be provided to the peripheral area PA. A printed circuit board including a built-in driving circuit portion for driving the pixels P, a power supply wiring, and a driving circuit portion, or terminals to which a driver integrated circuit (IC) is connected, may be arranged in the peripheral area PA.

An organic light-emitting diode OLED that is a display element of one pixel P may be connected to the pixel circuit PC. The pixel circuit PC may include a first thin-film transistor T1, a second thin-film transistor T2, and a storage capacitor Cst. The organic light-emitting diode OLED may emit red, green, or blue light, for example, or may emit red, green, blue, or white light.

The second thin-film transistor T2 may be a switching thin-film transistor, may be connected to the scan line SL and the data line DL, and may be configured to transmit a data voltage input from the data line DL in response to a switching voltage input from the scan line SL to the first thin-film transistor T1. The storage capacitor Cst may be connected to the second thin-film transistor T2 and the driving voltage line PL and may store a voltage corresponding to a difference between a voltage transmitted from the second thin-film transistor T2 and a first power supply voltage ELVDD supplied to the driving voltage line PL.

The first thin-film transistor T1 may be a driving thin-film transistor, may be connected to the driving voltage line PL and the storage capacitor Cst, and may control a driving current flowing through the organic light-emitting diode OLED from the driving voltage line PL in response to a voltage value stored in the storage capacitor Cst. The organic light-emitting diode OLED may emit light having certain luminance by using the driving current. An opposite electrode (e.g., a cathode) of the organic light-emitting diode OLED may receive a second power supply voltage ELVSS.

According to some embodiments, the pixel P may include additional components or fewer components than what is illustrated in FIG. 3 without departing from the spirit and scope of embodiments according to the present disclosure.

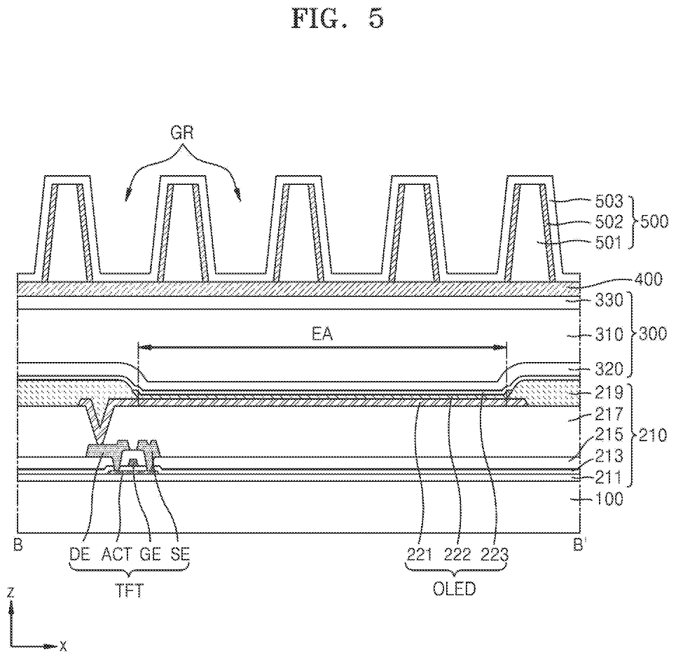

FIGS. 5 through 7 are cross-sectional views schematically illustrating a display apparatus taken along a line B-B′ of FIG. 4. For example, FIGS. 5 through 7 are cross-sectional views schematically illustrating a display apparatus taken along a line B-B′ of FIG. 4, according to some embodiments.

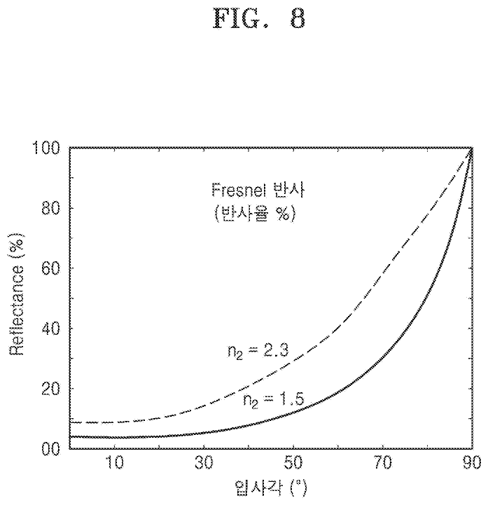

FIG. 8 is a graph schematically illustrating reflectance according to an incident angle of light incident from an emission layer to a refractive layer, depending on a refractive index of a highly refractive index layer.

Referring to FIGS. 5 through 7, a display apparatus according to some embodiments may include a substrate 100, a pixel circuit layer 210, an organic light-emitting diode OLED, an encapsulation layer 300, a touch sensor layer 400, and a light control layer 500.

As described above, the substrate 100 may include a glass material or a polymer resin. The pixel circuit layer 210 may be located on the substrate 100.

The pixel circuit layer 210 may include a thin-film transistor TFT and a storage capacitor. The thin-film transistor TFT may include a semiconductor layer ACT including amorphous silicon, polycrystalline silicon or an organic semiconductor material, a gate electrode GE, a source electrode SE, and a drain electrode DE. In order to ensure insulation between the semiconductor layer ACT and gate electrode GE, a gate insulating layer 213 including an inorganic material such as silicon oxide (SiOx), silicon nitride (SiNx) and/or silicon oxynitride (SiON) may be between the semiconductor layer ACT and the gate electrode GE.

An interlayer insulating layer 215 including an inorganic material such as silicon oxide (SiOx), silicon nitride (SiNx) and/or silicon oxynitride (SiON) may be located on the gate electrode GE, and the source electrode SE and the drain electrode DE may be located on the above-described interlayer insulating layer 215. An insulating layer including an inorganic material may be formed through atomic layer deposition (ALD). According to some embodiments, one of the source electrode SE and the drain electrode DE may be omitted and may be replaced with a conductive semiconductor layer ACT.

The gate electrode GE, the source electrode SE, and the drain electrode DE may be formed of various conductive materials. The gate electrode GE may include at least one of molybdenum (Mo), aluminum (Al), copper (Cu), or titanium (Ti), and may have a multi-layered structure according to some embodiments. For example, the gate electrode GE may have a single layer structure of Mo or a three-layer structure including a Mo layer, an Al layer, and a Mo layer. The source electrode SE and the drain electrode DE may include at least one of copper (Cu), Ti, or Al, and may have a multi-layered structure according to some embodiments. For example, the source electrode SE and the drain electrode DE may have a three-layer structure including a Ti layer, an Al layer, and a Ti layer.

A buffer layer 211 including an inorganic material, such as silicon oxide (SiOx), silicon nitride (SiNx) and/or silicon oxynitride (SiON) may be between the thin-film transistor TFT and the substrate 100. The buffer layer 211 may serve to increase the smoothness of a top surface of the substrate 100 or to prevent, reduce, or minimize the penetration of impurities or contaminants from the substrate 100 or the like into the semiconductor layer ACT of the thin-film transistor TFT.

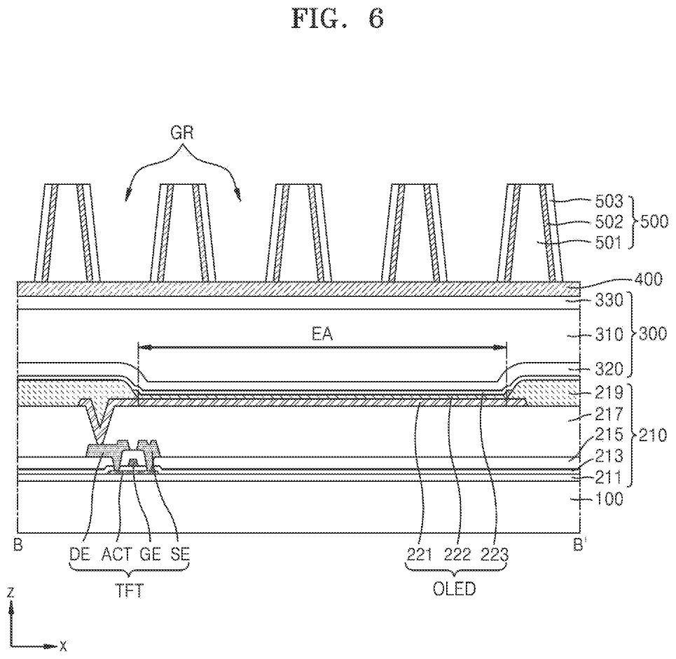

A planarization insulating layer 217 may be located on the thin-film transistor TFT. The planarization insulating layer 217 may include an organic material, such as acryl, benzocyclobutene (BCB), or hexamethyldisiloxane (HMDSO). In FIG. 6, the planarization insulating layer 217 is shown as a single layer but may also have a multi-layered structure.

The pixel electrode 221 may be located on the planarization insulating layer 217. The pixel electrode 221 may be located in each pixel. The pixel electrodes 221 corresponding to neighboring pixels may be arranged to be spaced apart from each other.

The pixel electrodes 221 may be reflective electrodes. According to some embodiments, each of the pixel electrodes 221 may include a reflective layer formed of silver (Ag), magnesium (Mg), Al, platinum (Pt), palladium (Pd), gold (Au), nickel (Ni), neodymium (Nd), iridium (Ir), chromium (Cr), and a compound thereof, and a transparent or (semi-)transparent electrode layer formed on the reflective layer. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). According to some embodiments, the pixel electrode 221 may have a three-layer structure of an ITO layer, an Ag layer, and an ITO layer.

A pixel-defining layer 219 may be located on the pixel electrode 221. The pixel-defining layer 219 may have an opening for exposing a top surface of each pixel electrode 221. The opening of the pixel-defining layer 219 may serve to define an emission area EA of the pixel. The pixel-defining layer 219 may cover the edge of the pixel electrode 221 and may increase a distance between the edge of the pixel electrode 221 and the opposing electrode 223, which may prevent or reduce instances of arcing or the like occurring at the edge of the pixel electrode 221. The pixel-defining layer 219 may include an organic insulating material such as polyimide, polyamide, an acryl resin, BCB, HMDSO, and a phenol resin, by using a method such as spin coating or the like. Alternatively, the pixel-defining layer 219 may include an inorganic insulating material. Alternatively, the pixel-defining layer 219 may have a multi-layered structure including an inorganic insulating material and an organic insulating material.

According to some embodiments, the pixel-defining layer 219 may include a light blocking material and may be colored black. The light blocking material may include carbon black, carbon nanotubes, a resin or paste including a black dye, metal particles, such as Ni, Al, Mo and alloys thereof, metal oxide particles (e.g., chromium oxide), or metal nitride particles (e.g., chromium nitride).

A light-emitting layer 222 may be located on the pixel electrode 221. The light-emitting layer 222 may include an organic material that includes a fluorescent or phosphorescent material capable of emitting red, green, or blue light. The above-described organic material may be a low molecular weight organic material or a polymer organic material. The light-emitting layer 222 may be arranged to correspond to the pixel electrode 221.

A first common layer and/or a second common layer may be located below and above the light emitting layer 222, respectively. The first common layer may be a component located below the light emitting layer 222 and may include, for example, a hole transport layer (HTL), or may include a hole transport layer and a hole injection layer (HIL). The second common layer may be a component located above the light emitting layer 222 and may include an electron transport layer (ETL) and/or an electron injection layer (EIL). In some embodiments, the second common layer may not be provided.

The first common layer and the second common layer may each be a common layer integrally formed to cover the substrate 100 as a whole, for example, the display area of the substrate 100, such as the opposite electrode 223, which will be described in more detail later.

The opposite electrode 223 may be a cathode, which is an electron implantation electrode, wherein a metal, alloy, electrically conductive compound, or any combination thereof having a low work function may be used as a material for the opposite electrode 223. The opposite electrode 223 may be a transmissive electrode, a semi-transmissive electrode, or a reflective electrode.

The opposite electrode 223 may include lithium (Li), Ag, Mg, Al, Al—Li, calcium (Ca), Mg—In, Mg—Ag, ytterbium (Yb), Ag—Yb, ITO, IZO, or any combination thereof. The opposite electrode 223 may have a monolayer structure, which is a single layer, or a multi-layered structure, which has a plurality of layers.

A capping layer may be further located on the opposite electrode 223. The capping layer may serve to improve the external luminous efficiency of an organic light-emitting device by the principle of constructive interference. The capping layer may include a material having a refractive index (at 589 nm) of 1.6 or more. The thickness of the capping layer may be from 1 nm to 200 nm, for example, 5 nm to 150 nm, or from 10 nm to 100 nm. The capping layer may be an organic capping layer including an organic material, an inorganic capping layer including an inorganic material, or a composite capping layer including an organic material and an inorganic material.

An encapsulation layer 300 for sealing a display element may be located on the organic light-emitting diode OLED. The encapsulation layer 300 may include at least one inorganic encapsulation layer and at least one organic encapsulation layer. At least one inorganic encapsulation layer may include one or more inorganic materials selected from the group consisting of aluminum oxide (Al₂O₃), titanium oxide (TiO₂), tantalum oxide (Ta₂O₅), zinc oxide (ZnO), silicon oxide (SiO₂), silicon nitride (SiNx), and silicon oxynitride (SiON). At least one organic encapsulation layer may include a polymer-based material. The polymer-based material may include an acryl-based resin, an epoxy-based resin, polyimide, polyethylene, or the like. According to some embodiments, at least one organic encapsulation layer may include acrylate. FIGS. 5 through 7 illustrate that the encapsulation layer 300 includes a first inorganic encapsulation layer 310, a second inorganic encapsulation layer 330 and an organic encapsulation layer 320 between the first inorganic encapsulation layer 310 and the second inorganic encapsulation layer 330. The organic encapsulation layer 320 may cover the unevenness of the organic light-emitting diode OLED to provide a flat top surface.

A touch sensor layer 400 may be located on the encapsulation layer 300. The touch sensor layer 400 may detect a user's touch input electrically or physically to transmit the user's touch input as an electrical signal to a display unit. According to some embodiments, the touch sensor layer 400 may be directly formed on the encapsulation layer 300. That is, the touch sensor layer 400 may include sensing patterns and insulating films formed directly on the encapsulation layer 300.

A light control layer 500 may be located on the touch sensor layer 400. The light control layer 500 may include a barrier layer 501, a light-absorbing layer 502, and a highly refractive index layer 503. Barrier layers 501 may be located on the substrate 100 to be spaced apart from each other in the first direction (e.g., an x direction or an −x direction). An empty space between the plurality of barrier layers 501 located on the substrate 100 may be defined as a groove GR.

According to some embodiments, the barrier layer 501 may be provided in the shape of a trapezoid. The barrier layer 501 may be provided in the shape of a trapezoid with a length of a side that is further spaced from the substrate 100 in the third direction (e.g., z direction) smaller than a length of a side that contacts the touch sensor layer 400. However, embodiments according to the present disclosure are not limited thereto. The barrier layer 501 may have a rectangular shape. In addition, the barrier layer 501 may be provided in the shape of a trapezoid with the length of the side that is further spaced from the substrate 100 in the third direction (e.g., z direction) greater than the length of the side that contacts the touch sensor layer 400.

The barrier layer 501 may include a transparent inorganic material or transparent polyimide. The barrier layer 501 may include a transparent inorganic material or transparent polyimide in such a way that light emitted in a direction perpendicular to the substrate 100 passes through the barrier layer 501. For example, the barrier layer 501 may include silicon dioxide (SiO₂), which is a transparent inorganic material. However, embodiments according to the present disclosure are not limited thereto.

The light-absorbing layer 502 may be located on the side of the barrier layer 501. For example, the light-absorbing layer 502 may be arranged to contact the sides of the barrier layer 501. The light-absorbing layer 502 may absorb at least a portion of light obliquely incident at an angle from the light-emitting layer 222 toward the light absorbing layer 502, thereby controlling the viewing angle of the display apparatus. The light-absorbing layer 502 may include amorphous silicon (a-Si) or silicon carbide (SiC). However, one or more embodiments are not limited thereto.

Referring to FIG. 5, the highly refractive index layer 503 may be continuously located on the substrate 100. The highly refractive index layer 503 may be located not only on the sides of the barrier layer 501, but also on the top surface of the barrier layer 501 and on the top surface of the touch sensor layer 400.

Referring to FIG. 6, according to some embodiments, the highly refractive index layer 503 may be located on the light-absorbing layer 502. The light-absorbing layer 502 may be located on the side of the barrier layer 501. The highly refractive index layer 503 may not be located on the top surface of the barrier layer 501 or on at least a portion of the top surface of the touch sensor layer 400.

Referring to FIGS. 5, 6, and 8, at least a portion of the light obliquely incident at an angle from the light-emitting layer 222 to the highly refractive index layer 503 may be reflected from the highly refractive index layer 503. When the refractive index of the highly refractive index layer 503 is 2.3, according to the Fresnel principle, about 60% or more of the light obliquely incident may be reflected in such a way that the angle of incidence from the light-emitting layer 222 to the highly refractive index layer 503 is greater than or equal to 70°. Contrary to this, when the refractive index of the highly refractive index layer 503 is 1.5, according to the Fresnel principle, the reflectance of light incident on the highly refractive index layer 503 may be smaller than the reflectance of light incident on the highly refractive index layer 503 when the refractive index of the highly refractive index layer 503 is 2.3. To increase the reflectance of light incident from the light-emitting layer 222 to the highly refractive index layer 503 and to improve the light extraction efficiency of the display apparatus, the refractive index of the highly refractive index layer 503 may be greater than or equal to 2 and less than or equal to 2.3.

When light incident from the light-emitting layer 222 to the highly refractive index layer 503 is reflected, the angle of incidence and the angle of reflection are the same. Thus, when the refractive index of the highly refractive index layer 503 is greater than or equal to 2 and less than or equal to 2.3, about 60% or more of the light incident from the light-emitting layer 222 to the highly refractive index layer 503 with an angle of incidence greater than or equal to 70° may be reflected as light with a reflection angle greater than or equal to 70°. In other words, when the refractive index of the highly refractive index layer 503 is greater than or equal to 2 and less than or equal to 2.3, about 60% or more of the light incident from the light-emitting layer 222 to the highly refractive index layer 503 at an angle of incidence greater than or equal to 70° may be reflected and emitted close to a direction perpendicular to the substrate 100. When the refractive index of the highly refractive index layer 503 is greater than or equal to 2 and less than or equal to 2.3, about 60% or more of lights obliquely incident may be emitted similarly to vertical light (or light emitted in the direction perpendicular to the substrate 100) in such a way that the angle of incidence from the light-emitting layer 222 to the highly refractive index layer 503 is greater than or equal to 70°, thereby controlling the viewing angle of the display apparatus. When the refractive index of the highly refractive index layer 503 is less than 2, according to the Fresnel principle, the reflectance of light incident on the highly refractive index layer 503 from the light-emitting layer 222 may be reduced so that the light extraction efficiency may be reduced. When the refractive index of the highly refractive index layer 503 exceeds 2.3, the absorption coefficient of the material may increase, causing the highly refractive index layer 503 to absorb most of the lights incident from the light-emitting layer 222 to the highly refractive index layer 503, so that the light extraction efficiency of the display apparatus may be reduced.

The highly refractive index layer 503 may include a material that is transparent and has a refractive index that is greater than or equal to 2 and less than or equal to 2.3. The highly refractive index layer 503 may include at least one selected from the group consisting of niobium pentoxide (Nb₂O₅), titanium dioxide (TiO₂), and tantalum pentoxide (Ta₂O₅).

In the related art, a light-absorbing layer (e.g., metal-oxide thin-film oxides (MTO)) is applied to an organic film barrier structure on a substrate to absorb obliquely-emitted light and transmit only vertically-emitted light so that the viewing angle of the display apparatus is controlled. In a process of removing at least a portion of a light-absorbing layer (e.g., MTO) formed on the organic film barrier structure by dry etching, the light-absorbing layer (e.g., MTO) located on the side of the organic layer barrier structure is vulnerable to erosion and may be damaged. Thus, the light-absorbing layer (e.g., MTO) formed on the organic film barrier structure is not uniformly thick, resulting in different light absorption rates depending on the height of the organic layer barrier structure. In addition, at least a portion of the light-absorbing layer (e.g., MTO) exposed in a dry etching process is developed and damaged in subsequent processes. Also, in the related art, only light vertically-emitted from the light-emitting layer is emitted, and obliquely-incident lights are absorbed by a light-absorbing layer (e.g., MTO) so that the viewing angle of the display apparatus is controlled.

According to some embodiments, a light-absorbing layer 502 including a-Si or SiC may be located on the barrier layer 501 by chemical vapor deposition (CVD), which may improve the degree of step coverage of the light-absorbing layer 502, and the highly refractive index layer 503 may be located on the light-absorbing layer 502, so that the light-absorbing layer 502 is not vulnerable to erosion in subsequent processes. Due to the light-absorbing layer 502, which is formed by a CVD method and has an improved degree of step coverage and the highly refractive index layer 503 located on the light-absorbing layer 502, the damage to the light-absorbing layer 502 in subsequent processes may be reduced, so that the stability of the process may be secured. In the related art, the light-absorbing layer (e.g., MTO) is vulnerable to erosion, requiring a separate process such as forming a protective layer on the light-absorbing layer (e.g., MTO). However, according to some embodiments, the degree of step coverage of the light-absorbing layer 502 may be improved, and a highly refractive index layer 503 may be located on the light-absorbing layer 502, so that a separate process such as forming a protective layer on the light-absorbing layer 502 may not be necessary, which may facilitate the manufacturing process of the display apparatus. In addition to light vertically emitted from the light-emitting layer 222, obliquely-emitted lights are reflected to be vertically emitted from the highly refractive index layer 503 according to the Fresnel principle, which may improve the light extraction efficiency of the display apparatus.

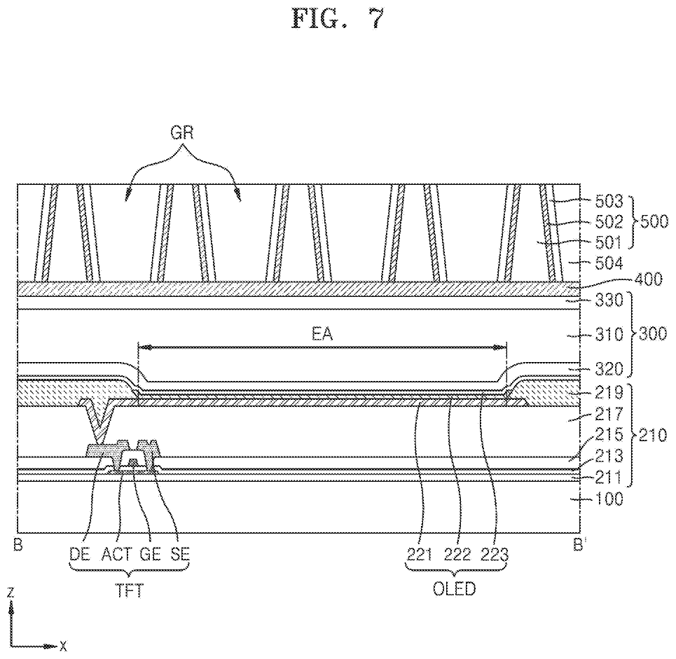

Referring to FIG. 7, according to some embodiments, grooves GR, which are empty spaces between the plurality of barrier layers 501, may be filled with an organic film 504. The refractive index of the organic film 504 may be greater than or equal to 1.5 and less than or equal to 1.6. The refractive index of the organic material employed by the display apparatus may generally be greater than or equal to 1.5 and less than or equal to 1.6. The organic film 504 may include transparent photosensitive polyimide (PSPI). In order for light emitted in a direction perpendicular to the substrate 100 to pass through the organic film 504 from the light-emitting layer 222 toward the organic layer 504, the organic film 504 may include a transparent material.

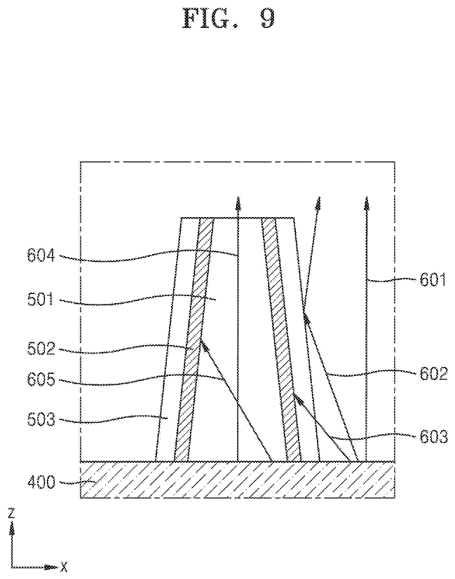

FIG. 9 is a cross-sectional view schematically illustrating lights incident on a light control layer.

Referring to FIG. 9, light may be emitted from the light-emitting layer 222 located below the light control layer 500 and thus may be incident on the light control layer 500. A first light 601 and a fourth light 604, which are emitted in a vertical direction (e.g., z direction or −z direction), of light emitted from the light-emitting layer 222 may be emitted through an empty space between the barrier layers 501 and the barrier layer 501. For example, the first light 601 emitted from the light-emitting layer 222 in the vertical direction (e.g., z direction or −z direction) may be emitted after passing through the touch sensor layer 400. In addition, the fourth light 604 emitted from the light-emitting layer 222 in the vertical direction (e.g., z direction or −z direction) may be emitted after passing through the barrier layer 501. Because the barrier layer 501 includes a transparent inorganic material or transparent polyimide, the fourth light 604 emitted from the light-emitting layer 222 in the vertical direction (e.g., z direction or −z direction) may be emitted through the barrier layer 501.

Second lights 602 obliquely incident from the light-emitting layer 222 to the highly refractive index layer 503 may be reflected and emitted as light close to the vertical direction (e.g., z direction or −z direction). According to the Snell's law, the angle of incidence of incident light and the angle of reflection of reflected light at a boundary may be the same. The angle of incidence of the second light 602 incident on the highly refractive layer 503 from the light-emitting layer 222 and the angle of reflection of the light reflected and emitted from the highly refractive index layer 503 may be the same. For example, when the angle of incidence of the second light 602 incident on the highly refractive index layer 503 from the light-emitting layer 222 is greater than or equal to 70°, the angle of reflection of the light reflected and emitted from the highly refractive index layer 503 may also be greater than or equal to 70°. In other words, when the angle of incidence of the second light 602 incident on the highly refractive index layer 503 from the light-emitting layer 222 is greater than or equal to 70°, the light reflected and emitted from the highly refractive index layer 503 may be light that is close to the vertical direction (e.g., z direction or −z direction).

According to Fresnel's law, depending on the refractive index of the highly refractive index layer 503, the reflectance of the second light 602 incident on the highly refractive index layer 503 from the light-emitting layer 222 may vary. Referring to FIG. 8, when the refractive index of the highly refractive index layer 503 is about 2.3, more than 60% of the second light 602 incident from the light-emitting layer 222 to the highly refractive index layer 503 at an angle of incidence greater than 70° may be reflected. In other words, when the refractive index of the highly refractive index layer 503 is about 2.3, the reflectance of the second light 602 is greater than or equal to 60%, so that most of the second lights 602 may be reflected from the highly refractive index layer 503, thereby improving the light extraction efficiency of the display apparatus.

A third light 603 emitted from the light-emitting layer 222 and penetrating the highly refractive index layer 503 may be absorbed by the light-absorbing layer 502 located on the side of the barrier layer 501. In order to control the viewing angle of the display apparatus, only light that is emitted in a vertical direction needs to be emitted, so that lights obliquely incident on the light-absorbing layer 502 may be absorbed by the light-absorbing layer 502 and may not be emitted.

The fifth light 605, which is emitted from the light-emitting layer 222 and obliquely incident into the barrier layer 501, may be kept inside the barrier layer 501 so that the viewing angle of the display apparatus may be controlled. Lights having an incidence angle below a threshold angle of the fifth light 605 emitted from the light-emitting layer 222 and obliquely incident into the barrier layer 501 may be absorbed by the light-absorbing layer 502 and may not be emitted. Lights having an incidence angle above the threshold angle of the fifth light 605 emitted from the light-emitting layer 222 and obliquely incident into the barrier layer 501 may be trapped inside the barrier layer 501 by total reflection and may not be emitted.

Consequently, the first light 601 and the fourth light 604, which are emitted from the light-emitting layer 222 in a vertical direction (e.g., z direction or −z direction) may be emitted through an empty space between the barrier layers 501 and the barrier layer 501. At least 60% of the second light 602 incident at an angle of incidence of 70⁰ or more from the light-emitting layer 222 to the highly refractive index layer 503 may be emitted as light in a direction similar to the vertical direction (e.g., z direction or −z direction). The third light 603 incident from the light-emitting layer 222 through the highly refractive index layer 503 toward the light-absorbing layer 502 and the fifth light 605 incident from the light-emitting layer 222 into the barrier layer 501 may be absorbed by the light-absorbing layer 502, or trapped inside the barrier layer 501 by total reflection, and may not be emitted outside the display apparatus. To control the viewing angle of a display apparatus, only light close to the vertical direction (e.g., z or −z direction) needs to be emitted. By emitting 60% of the second light 602 as light close to the vertical direction (e.g., z direction or −z direction), the light extraction efficiency of the display apparatus may be improved.

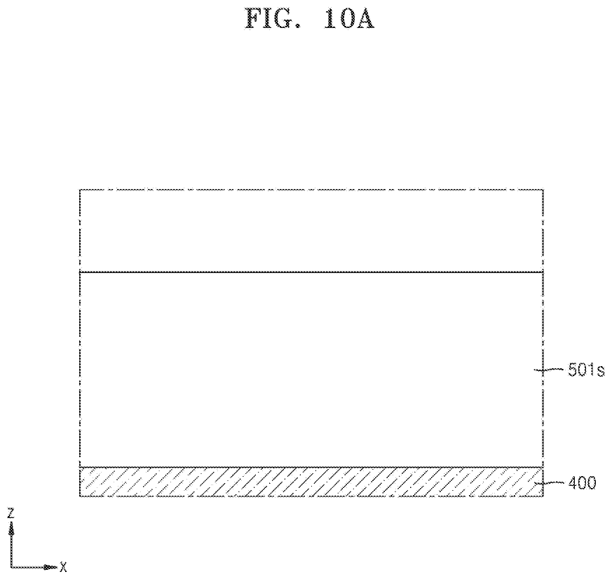

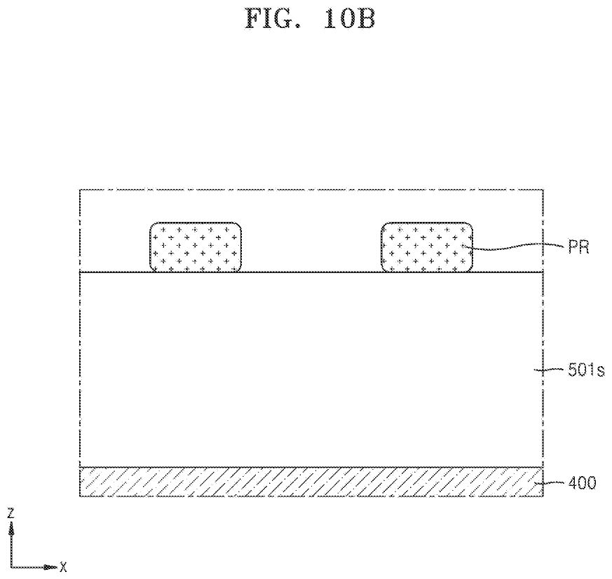

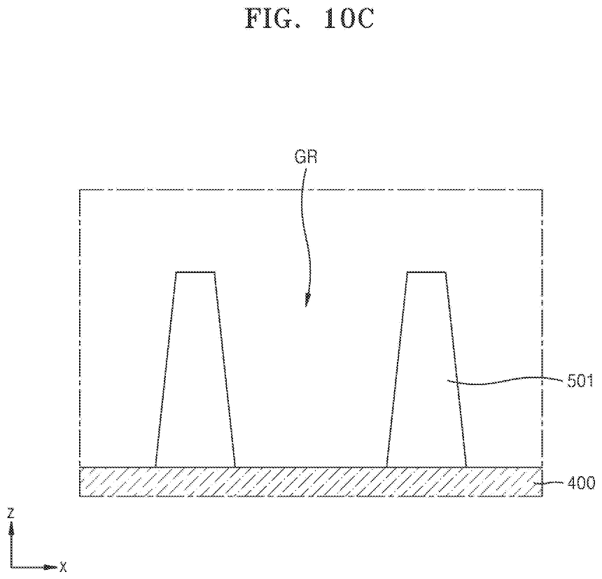

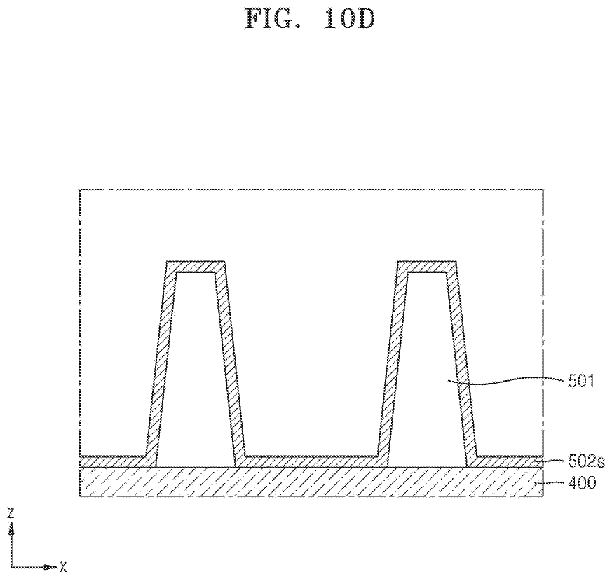

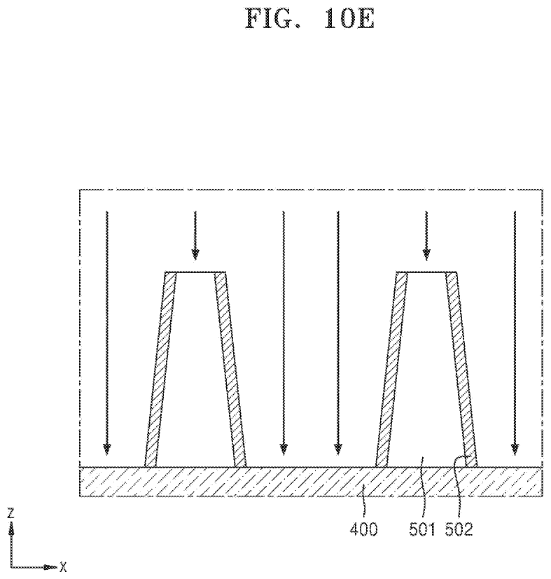

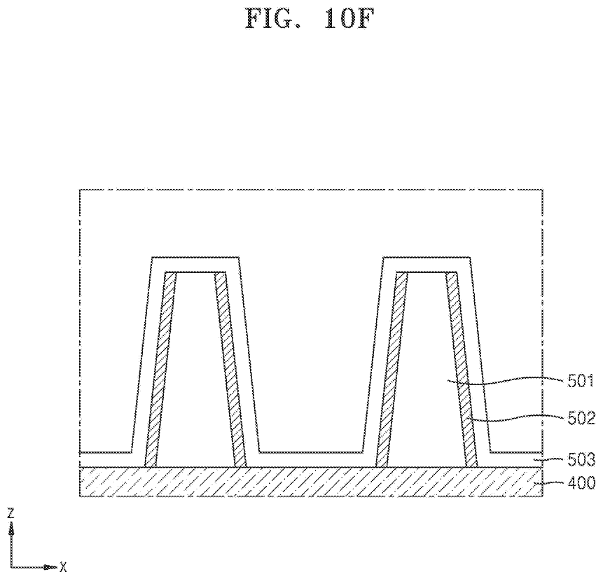

FIGS. 10A through 10F are cross-sectional views schematically illustrating a method of manufacturing a display apparatus according to some embodiments.

Referring to FIGS. 10A through 10F, the method of manufacturing a display apparatus may include forming a plurality of barrier layers 501 to be located on a substrate (see 100 of FIG. 5) and to be spaced apart from each other, the plurality of barrier layers 501 being transparent, forming a light-absorbing layer 502 arranged to contact sides of the barrier layers 501, and forming a highly refractive index layer 503 located on the light-absorbing layer 502.

A barrier layer-forming material 501s may be located on a touch sensor layer 400. The barrier layer-forming material 501s may include a transparent inorganic material or transparent polyimide. In order for light emitted from the light-emitting layer 222 in a vertical direction (e.g., a z direction) to be emitted to the exterior of the display apparatus, the barrier layer-forming material 501s may include a transparent inorganic material or transparent polyimide. For example, the barrier layer-forming material 501s may include silicon dioxide (SiO₂), which is a transparent inorganic material. However, one or more embodiments are not limited thereto.

A photoresist PR may be located on at least a portion of the barrier layer-forming material 501s. At least a portion of an upper portion of the barrier layer-forming material 501s in which the photoresist PR is not located, may be etched so that the barrier layer 501 may be formed. When the barrier layer-forming material 501s is etched, a taper angle may be adjusted by adjusting retraction by consuming the photoresist PR side so that the barrier layer 501 having a trapezoidal shape may be formed.

A plurality of barrier layers 501 may be spaced apart from each other on the touch sensor layer 400. An empty space between the barrier layers 501 may be defined as a groove GR. The barrier layer 501 may have a trapezoidal shape. The barrier layer 501 may be provided in the shape of a trapezoid with a length of a side that is further spaced from the substrate 100 in a third direction (e.g., z direction) smaller than a length of a side that contacts the touch sensor layer 400. However, one or more embodiments are not limited thereto. The barrier layer 501 may have a rectangular shape.

A light-absorbing layer-forming material 502s may be located on the barrier layer 501. The light-absorbing layer-forming material 502s may be deposited on the barrier layer 501 by using a CVD process. The degree of step coverage of the light-absorbing layer-forming material 502s formed by the CVD process may be excellent, and the thickness of the light-absorbing layer-forming material 502s may be uniform. Because the degree of step coverage of the light-absorbing layer-forming material 502s is excellent, the light-absorbing layer-forming material 502s is not vulnerable to erosion in subsequent processes or the like, and the degree of damage may be reduced.

The light-absorbing layer-forming material 502s may include a material capable of absorbing light. For example, the light-absorbing layer-forming material 502s may include a-Si or SiC. However, one or more embodiments are not limited thereto.

At least a portion of the light-absorbing layer-forming material 502s may be anisotropically dry etched to form the light-absorbing layer 502. For example, a portion of the light-absorbing layer-forming material 502s arranged in a horizontal direction (e.g., x direction or −x direction) may be removed by anisotropic dry etching to form the light-absorbing layer 502. The light-absorbing layer-forming material 502s located in the horizontal direction (e.g., x direction or −x direction) may be removed by etching to form the light-absorbing layer 502, which is arranged to contact the sides of the barrier layer 501. According to some embodiments, the light-absorbing layer 502 may not be located on the top surface of the barrier layer 501 and on at least a portion of the top surface of the touch sensor layer 400.

A highly refractive layer 503 may be formed on the light-absorbing layer 502. The highly refractive index layer 503 may be arranged continuously on the substrate 100. Because the highly refractive index layer 503 does not need to be uniformly thick, the highly refractive index layer 503 may be formed by sputtering. The highly refractive index layer 503 may include at least one selected from the group consisting of niobium pentoxide (Nb₂O₅), titanium dioxide (TiO₂), and tantalum pentoxide (Ta₂O₅).

The refractive index of the highly refractive index layer 503 may be greater than or equal to 2 and less than or equal to 2.3. According to the Fresnel principle, when the refractive index of the highly refractive index layer 503 is greater than or equal to 2 and less than or equal to 2.3, more than 60% of the light obliquely incident from the light-emitting layer 222 to the highly refractive index layer 503 is reflected and emitted in a vertical direction, so that the light extraction efficiency of the display apparatus may be improved.

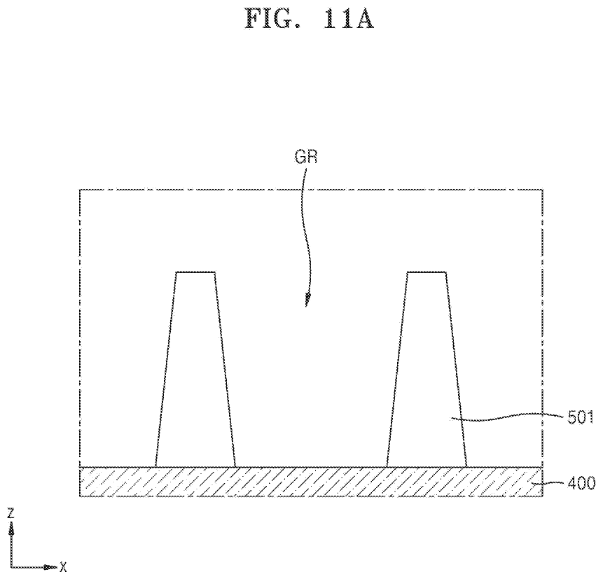

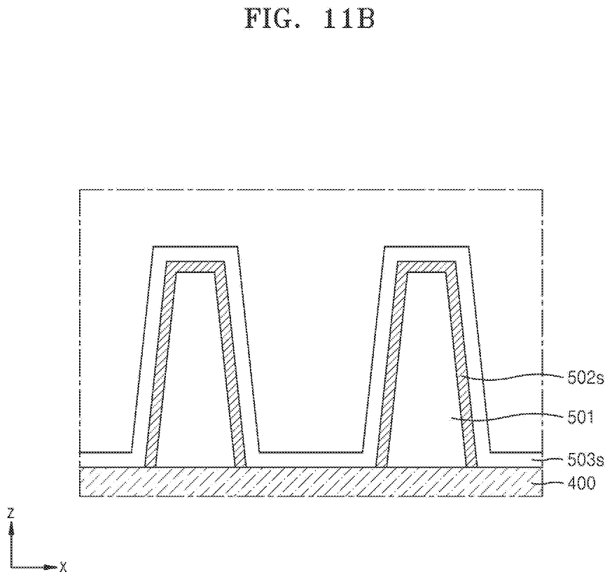

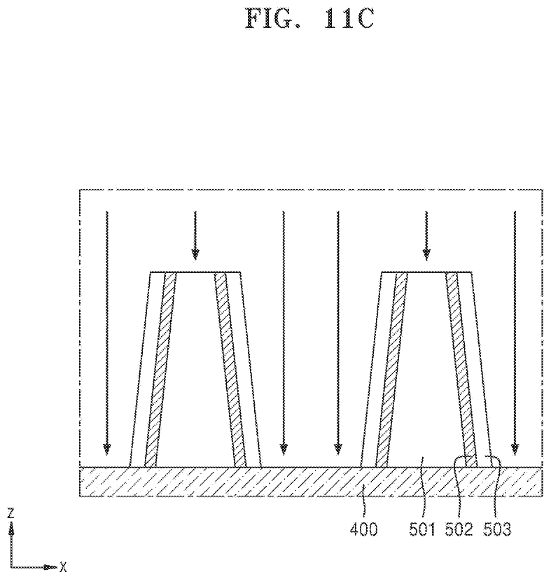

FIGS. 11A through 11C are cross-sectional views schematically illustrating a method of manufacturing a display apparatus according to some embodiments.

Referring to FIGS. 11A through 11C, a plurality of barrier layers 501 may be formed on the touch sensor layer 400 to be spaced apart from one another. An empty space between the barrier layers 501 may be defined as a groove GR. The barrier layer 501 may include a transparent inorganic material or transparent polyimide. For example, the barrier layer 501 may include silicon dioxide (SiO₂), which is a transparent inorganic material.

The barrier layer 501 may have a trapezoidal shape. The barrier layer 501 may be provided in the shape of a trapezoid with a length of a side that is further spaced from the substrate 100 in a third direction (e.g., z direction) smaller than a length of a side that contacts the touch sensor layer 400. However, one or more embodiments are not limited thereto. The barrier layer 501 may have a rectangular shape.

A light-absorbing layer-forming material 502s may be located on the barrier layer 501 by using CVD or any other suitable deposition method. The light-absorbing layer-forming material 502s is formed by using CVD so that the degree of step coverage of the light-absorbing layer-forming material 502s may be enhanced and the uniformity of the thickness of the light-absorbing layer-forming material 502s may be enhanced. The light-absorbing layer-forming material 502s may include a-Si or SiC. However, one or more embodiments are not limited thereto.

A highly refractive index layer-forming material 503s may be located on the light-absorbing layer-forming material 502s. Because the highly refractive index layer-forming material 503s does not need to be uniformly thick, the highly refractive index layer-forming material 503s may be formed by sputtering or any other suitable deposition method. The refractive index of the highly refractive index layer-forming material 503s may be greater than or equal to 2 and less than or equal to 2.3. The highly refractive index layer-forming material 503s may include at least one selected from the group consisting of niobium pentoxide (Nb₂O₅), titanium dioxide (TiO₂), and tantalum pentoxide (Ta₂O₅).

The light-absorbing layer 502 and the highly refractive index layer 503 may be formed by etching at least a portion of the light-absorbing layer-forming material 502s and the highly refractive index layer-forming material 503s located on the barrier layer 501. For example, the light-absorbing layer 502 and the highly refractive index layer 503 may be formed by anisotropically etching at least a portion of the light-absorbing layer-forming material 502s and the highly refractive index layer-forming material 503s located on the barrier layer 501. A portion of the light-absorbing layer-forming material 502s and the highly refractive index layer-forming material 503s arranged in the horizontal direction (e.g., x direction or −x direction) on the barrier layer 501 may be removed by anisotropic dry etching to form the light-absorbing layer 502 and the highly refractive index layer 503, respectively. The process may be facilitated by simultaneously removing the light-absorbing layer-forming material 502s and the highly refractive index layer-forming material 503s.

In the related art, light-absorbing layers (e.g., metal-oxide thin-film oxides (MTO)) are applied to organic film barrier structures on substrates to absorb oblique emitted light and transmit only vertically oriented light so that the viewing angle of the display apparatus is controlled. In a process for removing at least a portion of a light-absorbing layer (e.g., MTO) formed on an organic film barrier structure by dry etching, the light-absorbing layer (e.g., MTO) located on the side of the organic layer barrier structure is vulnerable to erosion and may be damaged. Thus, the light-absorbing layer (e.g., MTO) formed on the organic film barrier structure is not uniformly thick, resulting in different light absorption rates depending on the height of the organic layer barrier structure. In addition, at least a portion of the light-absorbing layer (e.g., MTO) exposed in the dry etch process is developed and damaged in subsequent processes. Also, in the related art, only light vertically emitted from the light-emitting layer is emitted, and obliquely-incident lights are absorbed by a light-absorbing layer (e.g., MTO) so that the viewing angle of the display apparatus is controlled.

According to some embodiments, a light-absorbing layer 502 including a-Si or SiC may be located on the barrier layer 501 by using CVD, which may improve the degree of step coverage of the light-absorbing layer 502, and the highly refractive index layer 503 may be located on the light-absorbing layer 502, so that the light-absorbing layer 502 is not vulnerable to erosion in subsequent processes. Due to the light-absorbing layer 502, which is formed by a CVD method and has an improved degree of step coverage and the highly refractive index layer 503 located on the light-absorbing layer 502, the damage to the light-absorbing layer 502 in subsequent processes may be reduced, thereby securing the stability of the process. In the related art, the light-absorbing layer (e.g., MTO) is vulnerable to erosion, requiring a separate process such as forming a protective layer on the light-absorbing layer (e.g., MTO). However, according to some embodiments, the degree of step coverage of the light-absorbing layer 502 may be improved, and a highly refractive index layer 503 may be located on the light-absorbing layer 502, so that a separate process such as forming a protective layer on the light-absorbing layer 502 may not be necessary, which may facilitate the manufacturing process of the display apparatus. In addition to light emitted vertically from the light-emitting layer 222, obliquely-emitted lights are also reflected from the highly refractive index layer 503 to be vertically emitted according to the Fresnel principle so that the light extraction efficiency of the display apparatus may be improved.

According to one or more embodiments having the above configuration, a display apparatus may have a viewing angle that is limited in one direction so that reflection by windows of a vehicle may be reduced and stability and easiness of processes and a light extraction efficiency may be relatively enhanced, and a method of manufacturing the display apparatus may be implemented. Of course, the scope of the present disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising:
a substrate;
a plurality of barrier layers on the substrate and spaced apart from each other, the plurality of barrier layers being transparent;
a light-absorbing layer contacting sides of each of the barrier layers; and
a highly refractive index layer on the light-absorbing layer.

2. The display apparatus of claim 1, wherein each of the barrier layers has a shape of a trapezoid.

3. The display apparatus of claim 1, wherein each of the barrier layers comprises a transparent inorganic material or transparent polyimide.

4. The display apparatus of claim 3, wherein each of the barrier layers comprises silicon oxide (SiO₂) which is a transparent inorganic material.

5. The display apparatus of claim 1, wherein the light-absorbing layer comprises amorphous silicon (a-Si) or silicon carbide (SiC).

6. The display apparatus of claim 1, wherein a refractive index of the highly refractive index layer is greater than or equal to 2 and less than or equal to 2.3.

7. The display apparatus of claim 1, wherein the highly refractive index layer comprises at least one of niobium pentoxide (Nb₂O₅), titanium dioxide (TiO₂), or tantalum pentoxide (Ta₂O₅).

8. The display apparatus of claim 1, further comprising:
grooves that are empty spaces between the barrier layers; and
an organic film filled in the grooves.

9. The display apparatus of claim 8, wherein a refractive index of the organic film is greater than or equal to 1.5 and less than or equal to 1.6.

10. The display apparatus of claim 8, wherein the organic film comprises transparent photosensitive polyimide (PSPI).

11. A method of manufacturing a display apparatus, the method comprising:
forming a plurality of barrier layers on a substrate and that are spaced apart from each other, the plurality of barrier layers being transparent;
forming a light-absorbing layer contacting sides of each of the barrier layers; and
forming a highly refractive index layer on the light-absorbing layer.

12. The method of claim 11, further comprising:
using a chemical vapor deposition (CVD) process to form a light-absorbing layer-forming material on each of the barrier layers; and
forming a light-absorbing layer by etching at least a portion of the light-absorbing layer-forming material.

13. The method of claim 12, further comprising forming a light-absorbing layer by etching a portion of the light-absorbing layer-forming material in a horizontal direction.

14. The method of claim 11, further comprising:
forming a light-absorbing layer-forming material on each of the barrier layers;
forming a highly refractive index layer-forming material on the light-absorbing layer-forming material; and
forming a light-absorbing layer and a highly refractive index layer by etching at least a portion of the light-absorbing layer-forming material and the highly refractive index layer-forming material.

15. The method of claim 14, further comprising forming a light-absorbing layer and a highly refractive index layer by etching a portion of the light-absorbing layer-forming material and the highly refractive index layer-forming material in a horizontal direction.

16. The method of claim 11, wherein each of the barrier layers comprises a transparent inorganic material or transparent polyimide.

17. The method of claim 16, wherein each of the barrier layers comprises silicon oxide (SiO₂) which is the transparent inorganic material.

18. The method of claim 11, wherein the light-absorbing layer comprises amorphous silicon (a-Si) or silicon carbide (SiC).

19. The method of claim 11, wherein a refractive index of the highly refractive index layer is greater than or equal to 2 and less than or equal to 2.3.

20. The method of claim 11, wherein the highly refractive index layer comprises at least one of niobium pentoxide (Nb₂O₅), titanium dioxide (TiO₂), or tantalum pentoxide (Ta₂O₅).
